(19) United States
(12) Patent Application Publication
(10) Pub. No.: US 2008/0191234 A1
(43) Pub. Date: Aug. 14, 2008

(54) YELLOW PHOSPHOR AND WHITE LIGHT EMITTING DEVICE USING THE SAME

(76) Inventors: Jun-Gill Kang, Daejeon (KR); Myoung-Kyo Kim, Chungju-si (KR)

Correspondence Address: KNOBBE MARTENS OLSON & BEAR LLP, 2040 MAIN STREET, FOURTEENTH FLOOR, IRVINE, CA, 92614, US

(21) Appl. No.: 12/025,632

(22) Filed: Feb. 4, 2008

Related U.S. Application Data
(63) Continuation of application No. PCT/KR2006/001549, filed on Apr. 25, 2006.

(30) Foreign Application Priority Data
Aug. 5, 2005 (KR) 10-2005-0071527

(51) Int. Cl. H01L 33/00; C01F 17/00; C09K 11/02

(52) U.S. Cl. 257/98; 423/263; 252/301.4 R; 257/E33.061

(57) ABSTRACT

Yellow phosphors which are excited by a blue light source and have a high luminescence efficiency are disclosed. Also disclosed is a method of synthesizing yellow phosphors which provides superior luminance and color purity. Also disclosed is a white light emitting device comprising the yellow phosphors which has a wide range for reproducing white colors so that a white light similar to a natural color may be obtained. One aspect of the present invention may provide a yellow phosphor represented by the following formula 1:

(Gd₁₋ₓTbₓ)₃(Ga_{1-y}Q_{y})₂Al₃O_{z}:aCe³⁺,bB³⁺ (1)
wherein Q is one or more elements selected from a group consisting of Si, Al, and Se; 0≦x≦0.1; 0≦y≦0.5; z is 12 when y is 0, 12 when Q is one or more elements selected from a group consisting of Al and Sc, or 12+y when Q is Si; a is 1 to 10 mole % of (Gd, Tb); and b is 0.5 to 4 moles per 1 mole of the host medium composition.

### CROSS-REFERENCE TO RELATED APPLICATIONS

This application is a continuation application, and claims the benefit under 35U.S.C. §§ 120 and 365 of PCT Application No. PCT/KR2006/001549, filed on Apr. 25, 2006, which is hereby incorporated by reference. The PCT application claims the benefit of Korean Patent Application No. 2005-0071527 filed on Aug. 5, 2005, which is hereby incorporated by reference.

### BACKGROUND OF THE INVENTION

1. Field of the Invention

The present disclosure relates to a phosphor, and in particular, to a yellow phosphor.

2. Description of the Related Technology

A light emitting diode (LED) is a state-of-the-art natural color display device and is known currently as one of the most highlighted areas of research due to its applicability in various indicators, TV's and flat panel displays. Such electroluminescence involves an electron, inputted from the negative pole, binding with an electron hole, formed at the positive pole, in the emission layer to form a “single exciton” when an electrical field is applied to a luminescent matter which is able to emit light. This single exciton forms an excited state, and in its transition to a ground state, various lights are emitted. The luminescent body based on this principle is a semiconductor element providing the benefits of a higher luminescent efficiency, lower power consumption, and greater thermal stability compared to conventional types, and is superior in terms of durability and response.

Among such LED's, the white light emitting diode (white LED) is currently the subject of vigorous research, for its applicability and marketability in household lighting, backlights of liquid crystal display panels, and car lighting, etc.

### SUMMARY OF CERTAIN INVENTIVE ASPECTS

One aspect of the present invention provides yellow phosphors that are excited by a blue light source to have a high luminescent efficiency. Another aspect of the present invention provides a method of preparing yellow phosphors which provides superior luminance and color purity and does not require a reducing atmosphere.

Another aspect of the present invention provides a white light emitting device comprising the yellow phosphors which has a wide range for reproducing white colors so that a white light similar to a natural color may be obtained.

Another aspect of the present invention may provide a yellow phosphor represented by the following formula 1:

(Gd₁₋ₓTbₓ)₃(Ga_{1-y}Q_{y})₂Al₃O_{z}:aCe³⁺,bB³⁺ (1)

wherein Q is one or more elements selected from a group consisting of Si, Al, and Sc; 0≦x≦0.1; 0≦y≦0.5; z is 12 when y is 0, 12 when Q is one or more elements selected from a group consisting of Al and Sc, or 12+y when Q is Si; a is about 1 to about 10 mole % of (Gd, Tb); and b is about 0.5 to about 4 moles per about 1 mole of the host medium composition.

Here, the phosphor may show an excitation band in the range of about 420 to about 520 nm and a luminescence band in about 475 to about 700 nm.

Another aspect of the present invention may provide a method of preparing a phosphor, comprising weighing and mixing one or more compounds selected from a group consisting of a Gd-containing compound, Ga-containing compound, Al-containing compound, Ce-containing compound, and B-containing compound, and optionally a Si-containing compound, Tb-containing compound or Sc-containing compound; and curing the compounds, said phosphor represented by the following formula 1:

(Gd₁₋ₓTbₓ)₃(Ga_{1-y}Q_{y})₂Al₃O_{z}:aCe³⁺,bB³⁺ (1)

wherein Q is one or more elements selected from a group consisting of Si, Al, and Sc; 0≦x≦0.1; 0≦y≦0.5; z is 12 when y is 0, 12 when Q is one or more elements selected from a group consisting of Al and Sc, or 12+y when Q is Si; a is about 1 to about 10 mole % of (Gd, Tb); and b is about 0.5 to about 4 moles per about 1 mole of the host medium composition.

Still another aspect of the present invention may provide a yellow phosphor represented by the following formula 2:

(Gd₁₋ₓ₋ₐTbₓ)₃(Ga_{1-y}Q_{y})₂Al₃O_{z}:3aCe³⁺,bB³⁺ (2)

wherein Q is one or more elements selected from a group consisting of Si, Al, and Sc; 0≦x≦0.1; 0≦y≦0.5; z is 12 when y is 0, 12 when Q is one or more elements selected from a group consisting of Al and Sc, or 12+y when Q is Si; a is about 1 to about 10 mole % of (Gd, Tb); and b is about 0.5 to about 4 moles per about 1 mole of the host medium composition.

Here, the phosphor may show an excitation band in the range of 420 to 520 nm and a luminescence band in 475 to 700 nm.

Still another aspect of the present invention may provide a white light emitting device comprising the yellow phosphors described above and a blue light emitting diode having a luminescence wavelength of 475 to 700 nm.

Hereinafter, the yellow phosphor, its preparation method, and the white light emitting device according to embodiments of the present invention will be described in detail.

Still another aspect of the present invention relates to a GGAG:B^{3÷} type phosphors in which B³⁺ is added to a garnet crystal having Gd, Ga, and Al as its main components, more specifically to a phosphor represented by the following formula 1.

(Gd₁₋ₓTbₓ)₃(Ga_{1-y}Q_{y})₂Al₃O_{z}:aCe³⁺,bB³⁺ (1)

wherein Q is one or more elements selected from a group consisting of Si, Al, and Sc; 0≦x≦0.1; 0≦y≦0.5; and z is 12 when y is 0, 12 when Q is one or more elements selected from a group consisting of Al and Sc, or 12+y when Q is Si.

Here, a is about 1 to about 10 mole % of (Gd, Tb), and b is about 0.5 to about 4 moles per about 1 mole of the host medium composition, or about 1 to about 2 moles. This is because mixing B³⁺ by the number of moles described above is suitable for increasing the luminescent efficiency of the phosphor.

In certain embodiments, a “k mole % of (Gd, Tb)” refers to the k mole concentration of Ce with respect to the sum of the mole concentrations of Gd and Tb, represented as a percentage. Also, “per 1 mole of the host medium composition” refers to the number of moles added per 1 mole of the (Gd₁₋ₓTbₓ)₃(Ga_{1-y}Q_{y})₂Al₃O_{z} composition. Also, the value of z being “12+y when Q is Si” means that when all or some of Q is substituted with Si, the value of the number of moles substituted plus 12 becomes the value of z.

Another aspect of the invention provides a yellow phosphor represented by Formula 1:

(Gd₁₋ₓTbₓ)₃(Ga_{1-y}Q_{y})₂Al₃O_{z}:aCe³⁺,bB³⁺ (1)

wherein Q is one or more elements selected from the group consisting of Si, Al, and Sc, wherein x is from about zero to about 0.1, wherein y is from about zero to about 0.5, wherein z is 12 when y is 0 or when Q is at least one of Al and Sc, wherein z is 12+y when Q is Si, wherein a is from about 0.03 to about 0.3, wherein b is from about 0.5 to about 4, a may be from about 1 to about 10 mole % of (Gd, Tb), and wherein b may be from about 0.5 to about 4 moles per 1 mole of (Gd₁₋ₓTbₓ)₃(Ga_{1-y}Q_{y})₂Al₃O₂.

The yellow phosphor may be produced by adding Ce in an amount from about 1 to about 10 mole % of a molar sum of Gd and Tb that are contained in Gd-containing compound(s) and Tb-containing compound(s). The yellow phosphor may be produced by adding B in an amount from about 50 to about 400 mole % of (Gd₁₋ₓTbₓ)₃(Ga_{1-y}Q_{y})₂Al₃O_{z}.

The phosphor may have an excitation band ranging from about 420 to about 520 nm. The phosphor may have a luminescence band ranging from about 475 to about 700 nm.

Q may be Si_{y1}Al_{y2}Sc_{y3}, wherein y may be y1+y2+y3, wherein y1 may be from about zero to about 0.5, wherein y2 may be from about zero to about 0.5, and wherein y3 may be from about zero to about 0.5. z may be 12 when y1=y2=y3=0, wherein z may be 12 when y1=0 and y2+y3≠0, and wherein z may be 12+y when y1≠0.9.

Another aspect of the invention provides a method of preparing the phosphor of claim 1, comprising: mixing one or more compounds selected from the group consisting of Gd-containing compounds, Ga-containing compounds, Al-containing compounds, Ce-containing compounds, and B-containing compounds, and optionally at least one selected from the group consisting of Si-containing compounds, Tb-containing compounds and a Sc-containing compound; and curing the compounds so as to produce the phosphor represented by Formula 1.

One or more Ce-containing compounds may be mixed in an amount from about 1 to about 10 mole % of a molar sum of Gd and Tb that are contained in one or more Gd-containing compounds and Tb-containing compounds. One or more B-containing compounds may be mixed in an amount from about 50 to about 400 mole % of (Gd₁₋ₓTbₓ)₃(Ga_{1-y}Q_{y})₂Al₃O_{z}.

Another aspect of the invention provides a white light emitting device comprising i) a yellow phosphor having a luminescence wavelength ranging from about 475 to about 700 nm and ii) a blue light emitting diode, wherein the yellow phosphor is represented by Formula 1:

(Gd₁₋ₓTbₓ)₃(Ga_{1-y}Q_{y})₂Al₃O_{z}:aCe³⁺,bB³⁺ (1)

wherein Q is one or more elements selected from the group consisting of Si, Al, and Sc, wherein x is from about zero to about 0.1, wherein y is from about zero to about 0.5, wherein z is 12 when y is 0 or when Q is at least one of Al and Sc, wherein z is 12+y when Q is Si, wherein a is from about 0.03 to about 0.3, and wherein b is from about 0.5 to about 4. In one embodiment, a is from about 1 to about 10 mole % of (Gd, Tb), and wherein b is from about 0.5 to about 4 moles per 1 mole of (Gd₁₋ₓTbₓ)₃(Ga_{1-y}Q_{y})₂Al₃O_{z}.

Another aspect of the invention provides a yellow phosphor represented by Formula 2:

(Gd₁₋ₓ₋ₐTbₓ)₃(Ga_{1-y}Q_{y})₂Al₃O_{z}:3aCe³⁺,bB³⁺ (2)

wherein Q is one or more elements selected from the group consisting of Si, Al, and Sc, wherein x is from about zero to about 0.1, wherein y is from about zero to about 0.5, wherein z is 12 when y is 0 or 12 when Q is at least one of Al and Sc, wherein z is 12+y when Q is Si, wherein a is from about 0.03 to about 0.3, and wherein b is from about 0.5 to about 4. The yellow phosphor may have an excitation band ranging from about 420 to about 520 nm and a luminescence band ranging from about 475 to about 700 nm.

Still another aspect of the invention provides a white light emitting device comprising i) a yellow phosphor having a luminescence wavelength ranging from about 475 to about 700 nm and ii) a blue light emitting diode, wherein the yellow phosphor is represented by Formula 2:

(Gd₁₋ₓ₋ₐTbₓ)₃(Ga_{1-y}Q_{y})₂Al₃O_{z}:3aCe³⁺,bB³⁺ (2)

wherein Q is one or more elements selected from the group consisting of Si, Al, and Sc, wherein x is from about zero to about 0.1, wherein y is from about zero to about 0.5, wherein z is 12 when y is 0 or 12 when Q is at least one of Al and Sc, wherein z is 12+y when Q is Si, wherein a is from about 0.03 to about 0.3, and wherein b is from about 0.5 to about 4. In one embodiment, a is from about 1 to about 10 mole % of (Gd, Tb), and wherein b is from about 0.5 to about 4 moles per 1 mole of (Gd₁₋ₓ₋ₐTbₓ)₃(Ga_{1-y}Q_{y})₂Al₃O_{z}.

### BRIEF DESCRIPTION OF THE DRAWINGS

FIG. 1 is a graph of XRD results of a Gd3Ga2Al3O12:Ce3+ phosphor.

FIG. 2 is a graph of XRD results of a phosphor represented by formula 1 according to one embodiment of the present invention.

FIG. 3 is an excitation spectrum (λems=550 nm) of a phosphor represented by formula 1 according to one embodiment of the present invention.

FIG. 4 is a luminescence spectrum (λexc=467 nm) of a phosphor represented by formula 1 according to one embodiment of the present invention, with respect to the amount of B3+ added.

FIG. 5 is a luminescence spectrum (λexc=467 nm) of a phosphor represented by formula 1 according to one embodiment of the present invention, with respect to the amount of Al added.

FIG. 6 is a luminescence spectrum (λexc=467 nm) of a phosphor represented by formula 2 according to another embodiment of the present invention, with respect to the amount of Si added.

FIG. 7 is a luminescence spectrum (λexc=467 nm) of a phosphor represented by formula 2 according to another embodiment of the present invention, with respect to the amount of Sc added.

FIG. 8 is a luminescence spectrum (λexc=467 nm) of a phosphor represented by formula 2 according to another embodiment of the present invention, with respect to the amount of Ce added.

FIG. 9 is a luminescence spectrum (λexc=467 nm) of a phosphor represented by formula 2 according to another embodiment of the present invention, with respect to the amount of Tb added.

FIG. 10 is a luminescence spectrum of a white light emitting diode manufactured using a phosphor according to one embodiment of the present invention.

### DETAILED DESCRIPTION OF CERTAIN INVENTIVE EMBODIMENTS

A method was studied for producing white light emitting elements by joining a yttrium aluminum garnet (Y₃Al₅O₁₂) based phosphorescent luminescent matter to a blue light emitting diode of a short-wavelength region such as in the blue light or ultraviolet ranges. (See S. Nakamura, The Blue Laser Diode, Springer-Verlag, pp 216-219 (1997)). With this method, generally white luminescence is induced as the combination of the blue LED light used as an excitation light and the yellow luminescence of the phosphor excited by the blue light. Light having a high excitation energy emitted from a high-luminance blue or ultraviolet short-wavelength light emitting diode excites a yellow phosphor to emit light in the yellow region. To obtain white light from the short-wavelength LED light source, the LED and a highly luminescent, high color rendering phosphor need to be combined.

There is a demand for the development of a suitable yellow phosphor, which can be prepared at the lowest possible temperature with a complete reduction during the curing process, and has a high luminosity. White light emitting phosphors for white type light emitting diodes currently used in practice include YAG-type and GAG-type phosphors (Nichia, U.S. Pat. No. 6,069,440; hereinafter referred to as the “'440 patent”), represented as (Re₁₋ᵣSmᵣ)₃(Al₁₋ₛGaₛ)₅O₁₂:Ce (where 0≦r≦1, 0≦s<1, Re: Y or Gd). Also, there is the TAG type phosphor (OSRAM, U.S. Pat. No. 6,504,179; hereinafter referred to as the “'179 patent”), in which Tb is added to the phosphor to cause a long-wave shift for a positive effect on the red component, represented by Tb₃(Al, Ga)₅O₁₂:Ce. However, a yellow phosphor having GGAG (gadolinium gallium aluminum garnet) as the host and Ce and B as activators, for use as a phosphor in white light emitting diodes, has not yet been presented.

The '440 patent mentioned above is limited in the tones of the emitted light, so that the white light emitting diode has a narrow range for reproducing white colors, and since the yellow color of the phosphor itself has a strong color, a portion of the blue light emission is absorbed into a white color.

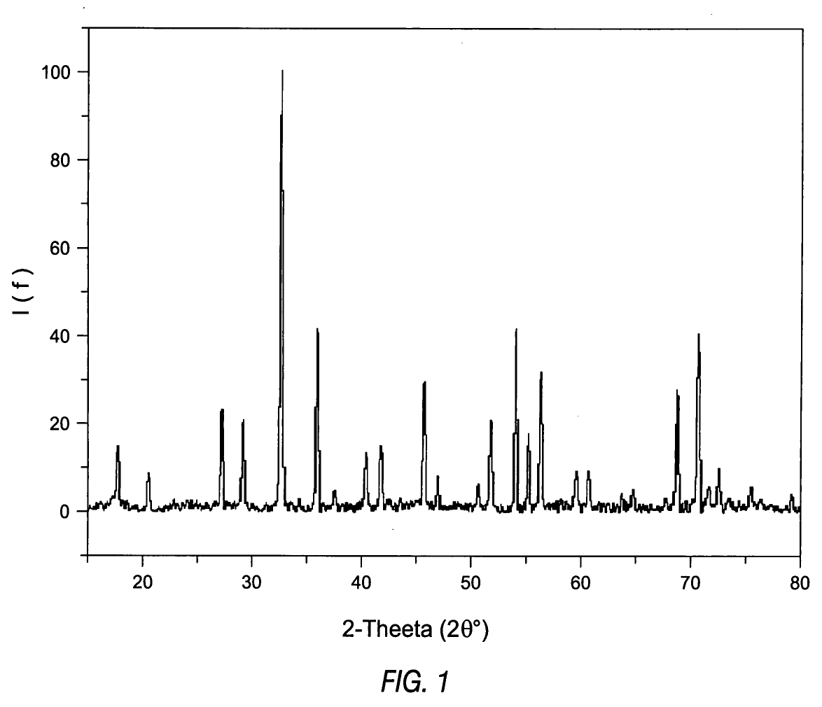

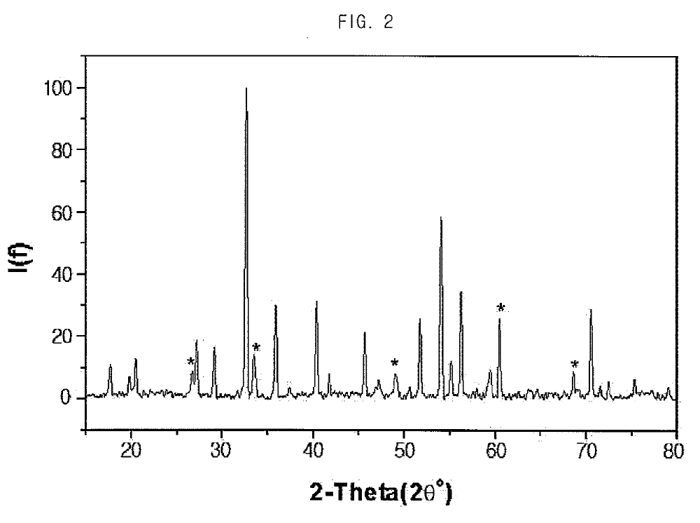

FIG. 1 is a graph of XRD) results of a Gd₃Ga₂Al₃O₁₂:Ce³⁺ phosphor, and FIG. 2 is a graph of XRD results of a phosphor represented by formula 1 according to one embodiment of the present invention. To examine changes with respect to the addition of B³⁺ ions, the XRD spectra were measured and compared for the Gd₃Ga₂Al₃O₁₂:Ce³⁺ and Gd₃Ga₂Al₃O₁₂:Ce³⁺,bB³⁺ phosphors. Also, Table 1 lists standard XRD data(JCPD) of conventional Y₃Al₅O₁₂, Gd₃Al₅O₁₂, and Gd₃Ga₂Al₃O₁₂ phosphors, and the 2θ and I(f) values measured in the present experiments.

TABLE 1

| | | | | | | | | Gd₃Ga₂Al₃O₁₂: | | Gd₃Ga₂Al₃O₁₂: | | Gd₃Ga₂Al₃O₁₂: | |
|---|---|---|---|---|---|---|---|---|---|---|---|---|---|
| Y₃Al₅O₁₂¹⁾ | | Ga₃Al₅O₁₂²⁾ | | Ga₃Ga₂Al₃O₁₂³⁾ | | Gd₃Ga₂Al₃O₁₂ | | Ce³⁺, 0.5B³⁺ | | Ce³⁺, 2B³⁺ | | Ce³⁺, 4B³⁺ | |
| 2θ | I(f) | 2θ | I(f) | 2θ | I(f) | 2θ | I(f) | 2θ | I(f) | 2θ | I(f) | 2θ | I(f) |
| 18.070 | 27.0 | 17.905 | 60.0 | 17.750 | 9.0 | 17.725 | 26.9 | 17.58 | 15.0 | 17.64 | 11.1 | 17.7 | 15.5 |
| — | — | 20.736 | 40.0 | 20.529 | 5.0 | — | — | 19.72 | 0.9 | 20.44 | 12.9 | 19.84 | 10.7 |
| — | — | — | — | — | — | — | — | 26.48 | 1.7 | 26.68 | 9.1 | 26.76 | 15.7 |
| 27.769 | 19.0 | 27.506 | 40.0 | 27.289 | 13.0 | 27.26 | 24.2 | 27.1 | 13.6 | 27.16 | 18.9 | 27.24 | 12.4 |
| 29.736 | 27.0 | 29.454 | 60.0 | 29.214 | 18.0 | 29.18 | 17.1 | 29.02 | 15.3 | 29.12 | 16.5 | 29.18 | 16.4 |
| 33.317 | 100.0 | 33.014 | 100.0 | 32.754 | 100.0 | 32.74 | 100.0 | 32.6 | 100.0 | 32.62 | 100.0 | 32.7 | 100.0 |
| — | — | — | | 34.399 | 1.0 | 33.66 | 1.8 | 33.66 | 5.7 | 33.46 | 14.1 | 33.56 | 23.2 |
| 36.618 | 20.0 | 36.342 | — | 35.984 | 27.0 | 35.98 | 30.8 | 35.8 | 32.1 | 35.86 | 30.0 | 35.94 | 27.9 |
| 41.147 | 23.0 | 40.739 | 70.0 | 40.414 | 18.0 | 40.42 | 37.5 | 40.24 | 18.2 | 40.3 | 31.2 | 40.36 | 24.0 |
| — | — | 42.111 | 50.0 | — | — | — | — | — | — | — | — | — | — |
| 46.60 | 26.0 | 46.133 | 20.0 | 45.754 | 22.0 | 45.8 | 29.5 | 45.58 | 25.1 | 45.62 | 21.4 | 45.72 | 26.1 |
| — | — | — | 60.0 | — | — | — | — | 49.12 | 1.1 | 49.12 | 6.8 | 49.14 | 13.6 |
| 52.780 | 17.0 | 52.228 | — | 51.823 | 26.0 | 51.84 | 20.8 | 51.64 | 31.4 | 51.7 | 25.7 | 51.82 | 30.9 |
| | | 54.616 | 60.0 | 54.109 | 46.0 | 54.1 | 41.5 | 53.94 | 41.7 | 54.04 | 58.4 | 54.08 | 44.6 |
| 55.107 | 31.0 | 55.695 | 60.0 | 55.228 | 9.0 | 55.26 | 17.5 | 55.04 | 9.7 | 55.1 | 12.2 | 55.18 | 13.3 |
| 57.377 | 28.0 | 56.898 | 20.0 | 56.328 | 38.0 | 56.34 | 21.6 | 56.14 | 35.0 | 56.22 | 34.5 | 56.3 | 40.0 |
| | | 59.981 | 60.0 | 59.563 | 6.0 | 59.58 | 9.0 | 59.38 | 6.1 | 59.42 | 9.2 | 59.5 | 12.4 |
| 61.770 | 10.0 | 61.075 | 20.0 | 60.608 | 19.0 | 60.7 | 9.0 | 60.44 | 14.3 | 60.44 | 26.0 | 60.6 | 30.8 |
| | | 69.463 | 40.0 | 70.643 | 37.0 | 68.78 | 27.4 | 68.5 | 10.6 | 68.58 | 9.1 | 68.66 | 9.6 |
| | | 71.152 | 30.0 | 71.598 | 5.0 | 70.74 | 40.4 | 70.46 | 35.6 | 70.52 | 28.8 | 70.62 | 37.6 |
| 72.018 | 17.0 | 72.222 | 60.0 | 72.568 | 9.0 | 72.56 | 9.7 | 72.38 | 12.3 | 72.44 | 5.8 | 72.52 | 10.3 |
| | | | 20.0 | | | | | | | | | | |

¹⁾JCPDs, PDF#33-0040
²⁾JCPDs, PDF#32-0383
³⁾JCPDs, PDF#46-0448

Referring to Table 1, as the Gd³⁺ ions are substituted instead of the y31 ions in the YAG-type phosphor, i.e. Y₃Al₅O₁₂, and the GAGtype phosphor, i.e. Gd₃Al₅O₁₂, which have the same garnet structure, the 2θ values for a given (h, k, l) are slightly decreased. For example, in the case of the (4, 2, 0) lattice, which shows the greatest intensity, a change of about −0.3° occurred for GAG compared with YAG. This is because the Gd³⁺ (about 1.05 Å) ions were substituted, which have an ion radius greater than that of the Y³⁺ (about 1.02 Å) ions. Further, for a given (h, k, l), the changes in the values of I(f) of YAG and GAG are quite large. Moreover, peaks that are not observed for YAG appear for the GAG structure with considerably high intensities. Similarly, in the case of GGAG, which is Gd₃Ga₂Al₃O₁₂, where the Al³⁺ (4-coordination: about 0.39 Å, 6-coordination: about 0.54 Å) ion is substituted by the Ga³⁺ (4-coordination: about 0.47 Å, 6-coordination: about 0.62 Å) ion in GAG, the values of 3θ were decreased, and there were significant changes in the values of J(f) for a given (h, k, l).

Referring to FIG. 2, the peaks denoted by * on the XRD spectrum of Gd₃Ga₂Al₃O₁₂:Ce³⁺,2B³⁺ are peaks that have newly appeared or peaks that have large changes in the values of 1(f) with the addition of B³⁺ ions. The peaks occurring at about 26.7°, 33.5°, and 49.1° are newly appeared peaks. Also, as seen in Table 1, the intensity of these peaks increases with the increase in the content of B³⁺ ions. For instance, the intensity of the peak at about 60.4° increased markedly with an increase in the content of B³⁺ ions, whereas the intensity of the peak at about 68.7° decreased markedly. These results show a significant effect of B³⁺ ions as a dopant on the crystal structure of GGAG, by which the luminescence intensity of GGAG is greatly affected.

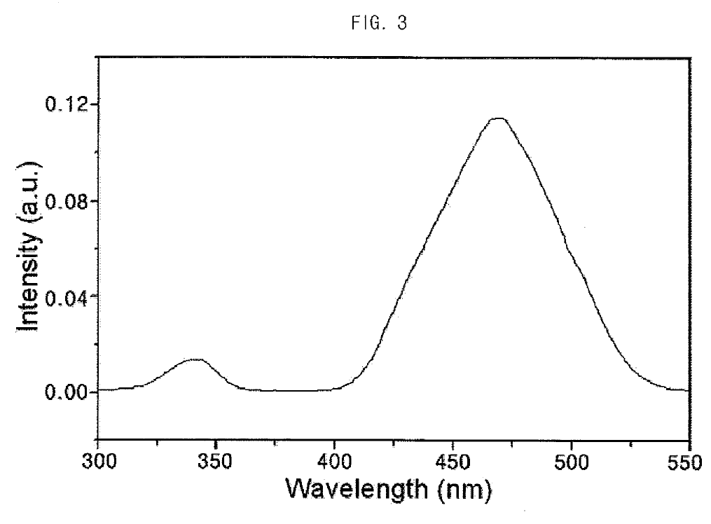

FIG. 3 illustrates an excitation spectrum (λₑₘₛ=about 550 nm) of a phosphor represented by formula 1 according to one embodiment of the present invention. FIG. 3 shows a small peak at about 345 nm and a large peak at about 470 nm. The large peak shows a broad absorption wavelength in the region of about 420 to about 520 nm. The sharp scattered light of the Xe lamp generally found in the region of about 450 to about 500 nm is detected and compensated for.

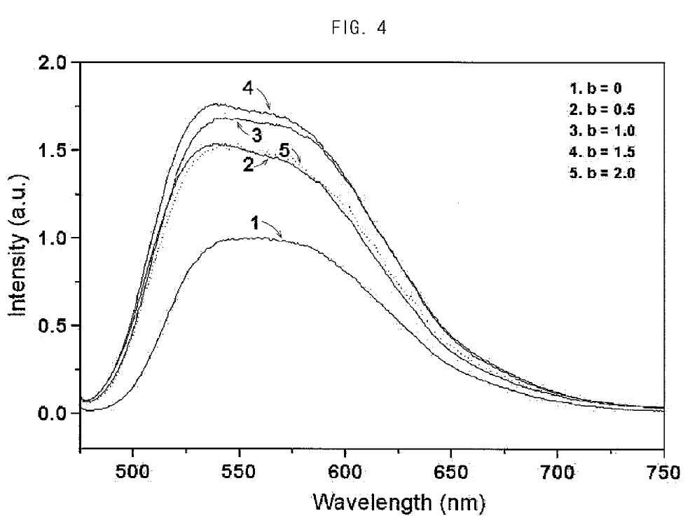

FIG. 4 represents a luminescence spectrum (λ_{exc}=about 467 nm) of a phosphor represented by formula 1 according to one embodiment of the present invention, with respect to the amount of B³⁺ added. Referring to FIG. 4, the more the number of moles of B³⁺ is increased for a constant value of Ce, the more the luminescence intensity is increased, and the luminescence intensity becomes a maximum when about 1.5 moles are added per 1 mole of the host medium composition. The luminescence spectrum, appearing in the region of about 475 to about 700 nm, is composed of two components peaking at about 520 and about 570 nm, respectively. In addition, for the case where b is 0, i.e. when B³⁺ is not added, it is seen that the Luminescence Intensity is significantly low, compared to the case in which B³⁺ is added, so that the luminance is low.

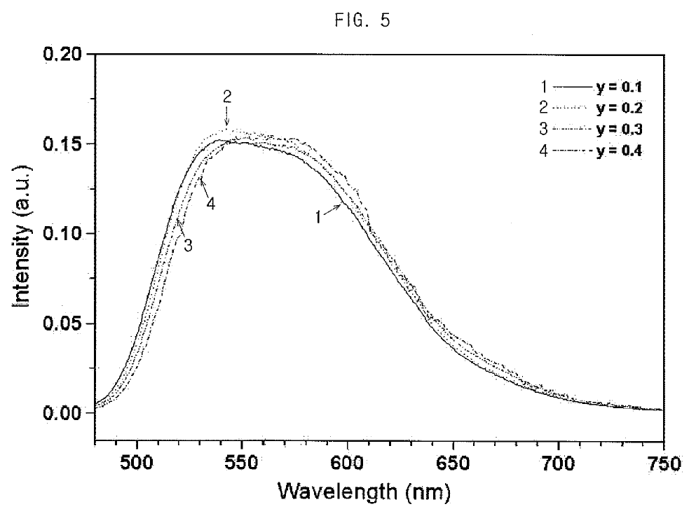

FIG. 5 shows a luminescence spectrum (λ_{exc}=about 467 nm) of a phosphor represented by formula 1 according to one embodiment of the present invention, with respect to the amount of Al added. Referring to FIG. 5, substituting with Al³⁺, which has a smaller ion radius than that of Ga³⁺, the ratio of the emission intensity of about 570 nm with respect to the emission intensity of about 520 nm is increased, so that the luminescence spectrum is generally moved towards long wavelengths.

Another embodiment of the present invention provides GGAG:B³⁺ type phosphor, in which B³⁺ is added to a garnet crystal having Gd, Ga, and Al as its main components, more specifically to a phosphor represented by the following formula 2:

(Gd₁₋ₓ₋ₐTbₓ)₃(Ga_{1-y}Q_{y})₂Al₃O_{z}:3aCe³⁺,bB³⁺ (2)

wherein Q is one or more elements selected from the group consisting of Si, Al, and Sc, wherein x is from about zero to about 0.1, wherein y is from about zero to about 0.5, wherein z is 12 when y is 0 or 12 when Q is at least one of Al and Sc, wherein z is 12+y when Q is Si. In one embodiment, a is from about 0.03 to about 0.3, wherein b is from about 0.5 to about 4.

In another embodiment, a is about 1 to about 10 mole % of (Gd, Tb), and b is about 0.5 to about 4 moles per about 1 mole of the host medium composition, or about 1 to about 2 moles. This is because mixing B³⁺ by the number of moles described above is suitable for increasing the luminescence efficiency of the phosphor. In another embodiment, Q is Si_{y1}Al_{y2}Sc_{y3}, wherein y is y1+y2+y3, wherein y1 is from about zero to about 0.5, wherein y2 is from about zero to about 0.5, wherein y3 is from about zero to about 0.5. In another embodiment, z is 12 when y1=y2=y3=0, wherein z is 12 when y1=0 and y2+y3≠0, wherein z is 12+y when y1≠0.

Whereas the activator Ce fills up the spaces in-between lattices in the phosphor of formula 1, in the phosphor of formula 2 it is substituted in the place of Gd to compose the phosphor. However, there is a common feature of having B³⁺ with a GGAG base, and thus the excitation spectrum of this phosphor is similar to that illustrated in FIG. 3, and its graph of XRD results is also similar to FIG. 2, but is different from the XRD results of FIG. 1 where B³⁺ is not included.

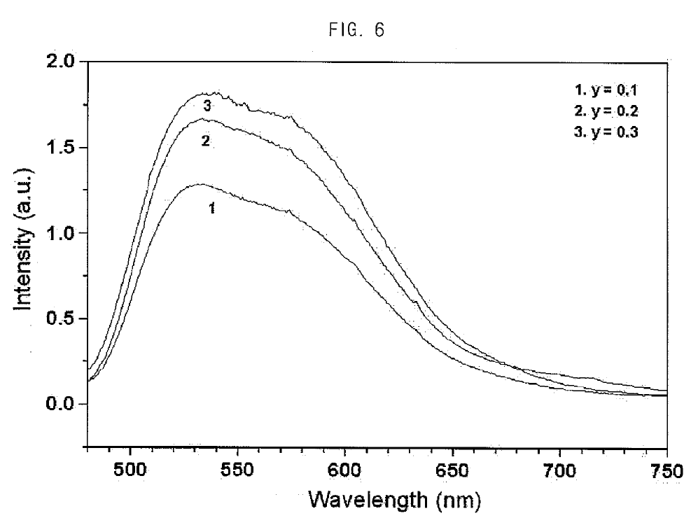

FIG. 6 is a luminescence spectrum (λ_{exc}=about 467 nm) of a phosphor represented by formula 2 according to one embodiment of the present invention, with respect to the amount of Si added. Referring to FIG. 6, it is seen that the phosphorescent intensity is greatly increased as Si is substituted in the place of Ga. This may be associated with the cation compensation vacancy defect generated when the Si having a +4 charge is substituted in the place of Ga having a +3 charge.

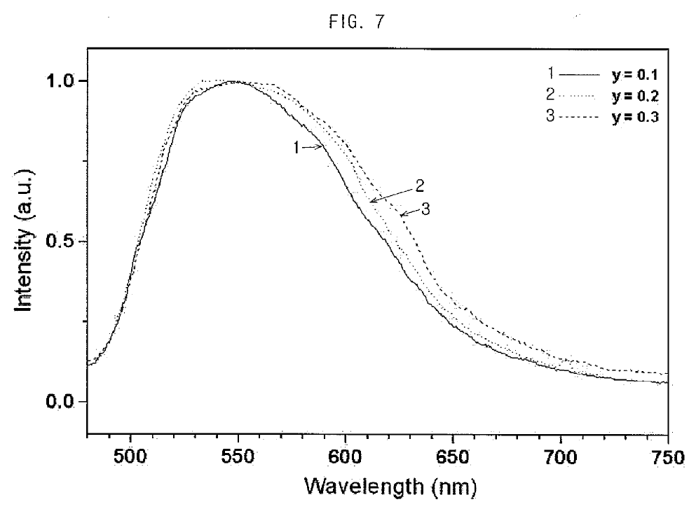

FIG. 7 is a luminescence spectrum (λexc=about 467 nm) of a phosphor represented by formula 2 according to one embodiment of the present invention, with respect to the amount of Sc added. Referring to FIG. 7, when a portion of Ga³⁺ having coordination numbers of 4 and 6 is substituted by Sc³⁺ having a coordination number of 6, the ratio of the emission intensity of about 570 nm with respect to the emission intensity of about 520 nm is increased, so that the luminescence spectrum is generally moved towards long wavelengths.

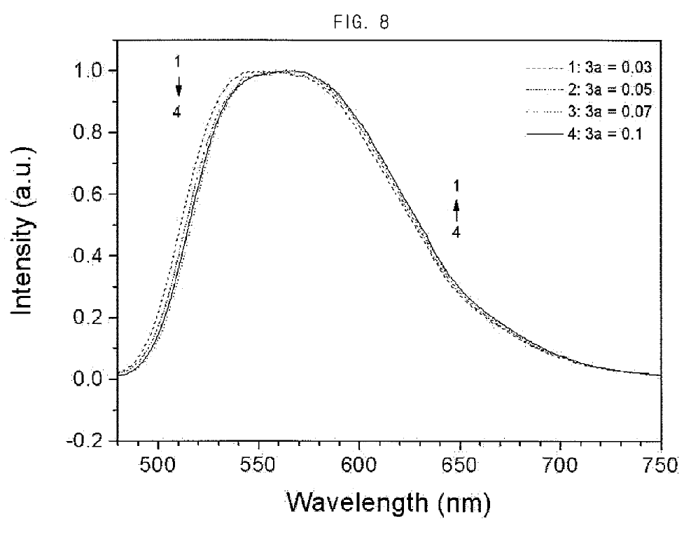

FIG. 8 is a luminescence spectrum (λ_{exc}=about 467 nm) of a phosphor represented by formula 2 according to one embodiment of the present invention, with respect to the amount of Ce added. Referring to FIG. 8S when Ce³⁺ is substituted in the place of Gd³⁺, the luminescence spectrum is towards long wavelengths.

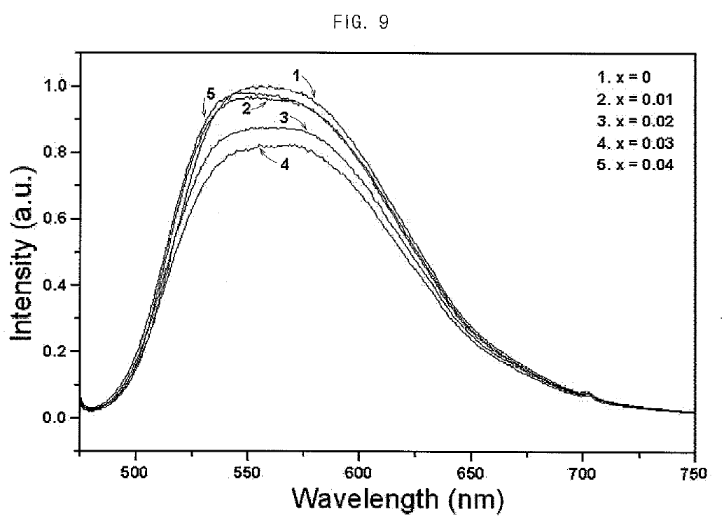

FIG. 9 is a luminescence spectrum (λ_{exc}=about 467 nm) of a phosphor represented by formula 2 according to one embodiment of the present invention, with respect to the amount of Tb added. Referring to FIG. 9, when Tb³⁺ is substituted in the place of Gd³⁺ and the substituted amount is increased, the luminescence intensity decreases and then increases again.

The phosphors of formula 1 and formula 2 characterized by the above are yellow phosphors having superior luminance and color purity, which may be excited by a blue wavelength of about 460 nm for use in blue LED's. Moreover, the phosphors based on one embodiment of the present invention has maximum values in a broad region of about 520 to about 580 nm, and are thus luminescent in various colors from the green to the yellow regions. Also, the luminescence efficiency is high, so that a phosphor having superior luminance and color rendering may be obtained, and with a white light emitting device manufactured using such phosphors, a white color similar to a natural color may be expressed. In addition, the luminescence region is broad, so that there is reduced risk of color omission when the emitted light is combined with blue light, whereby a white light emitting diode may be formed without a risk of second-order phases.

The foregoing provided detailed explanations on the phosphors, and hereinafter, a method of preparing the phosphors will be described in detail.

A method of preparing a phosphor, based on one embodiment of the present invention, may comprise weighing and mixing a Gd-containing compound, Ga-containing compound, Al-containing compound, Ce-containing compound, and B-containing compound, and optionally a Si-containing compound, Tb-containing compound, or Sc-containing compound with a solvent, and placing the mixture thus obtained in a high-purity alumina crucible and curing.

Here, the Gd-containing compound may be selected from, but is not limited to, Gd₂O₃, Gd(CO₃)₃, Gd(OH)₃, and Gd(NO₃)₃. Also, the Ga-containing compound may be selected from, but is not limited to, Ga₂O₃, Ga(CO₃)₃, Ga(OH)₃, and Ga(NO₃)₃. Here, the Al-containing compound may be selected from, but is not limited to, Al₂O₃, Al₂(CO₃)₃, Al(OH)₃, Al(NO₃)₃, and a compound forming a coprecipitated compound with Al.

Also, the Cc-containing compound may be selected from, but is not limited to, CeO₂, Ce₂(C₂O₄)₃, and a compound forming a coprecipitated compound with Ce. CeO₂ and Ce₂(C₂O₄)₃ may not require a reducing atmosphere. Also, the B-containing compound may be selected from, but is not limited to, B₂O₃, H₃BO₃, B₂(CO₃)₃, B(OH)₃, and B(NO₃)₃.

The Tb-containing compound, which may optionally be added, may be selected from, but is not limited to, Tb₄O₇, Tb₂(C₂O₄)₃, and a compound forming a coprecipitated compound with Tb, where Tb₄O₇ and Tb₂(C₂O₄)₃ may not require a reducing atmosphere, especially Tb₂(C₂O₄)₃. Also, the Si-containing compound may be selected as, but is not limited to, SiO₂, and the Sc-containing compound may be selected from, but is not limited to, Sc₂O₃, Sc(CO₃)₃, Sc(OH)₃, Sc(NO₃)₃.

In an embodiment of the present invention, when CeO₂ is used as a starting material producing a phosphor activated by Ce, a reducing gas is required since the oxidation number of Ce has to be reduced from a charge of +4 to a charge of +3. Thus, the reaction is performed in an open reaction container.

In another embodiment of the present invention, to perform a preparation method which provides high crystallinity and easy control of crystallinity without requiring a reducing atmosphere for reducing Ce ions during curing, the starting matter of Ce₂(C₂O₄)₃ may be used. Therefore, the reaction may be performed in a covered reaction container. Since the reaction does not use a reducing gas supplied from an outside source, but instead a sufficient reaction is achieved with the gas created inside the container, only the reaction time and the temperature may be adjusted to obtain the desired crystallinity. Also, by using a covered reaction container, the generation rate of CO₂ gas that occur during the curing may be mitigated, by which the equilibrium of the decomposition reaction of Ce oxalate may sufficiently be maintained.

In one embodiment of the present invention, Gd₂O₃, Ga₂O₃, Al₂O₃, Ce₂(C₂O₄)₃, and B₂O₃ are used as the starting materials for preparing a CGAG:B³⁺-type phosphor, in which B is added. These starting materials are mixed in the necessary stoichiometric proportions, and a fluorine compound is used on the mixture as a flux. Examples of a fluorine compound include aluminum fluoride (AlF₃), barium fluoride (BaF₂), and ammonium fluoride (NH₄F). Also, chlorides such barium chloride (BaCl₂) and ammonium chloride (NH₄Cl) may be used as the flux. The mixture and the flux are mixed in the appropriate amounts. Here, the appropriate amounts refer to mixing in about 10 to about 30 mole % with respect to the composition formula for the flux, such as ammonium fluoride, and in about 5 to about 20 weight % for the chlorides. The mixture with the flux mixed in is placed in a sealed kiln and undergoes a first curing at about 1000 to about 1600° C. for about 1 to about 48 hours. The curing may be performed at about 1350 to about 1550° C. for about 6 to about 8 hours. The capped container may be a high-purity alumina crucible. The cured matter is ground in a mortar, and then the powder is cleansed with a about 2 to about 5 weight % aqueous hydrochloric acid solution to remove the flux, is separated and dried, after which a second curing is performed in a mixed gas of H₂/N₂. The composition of the H₂/N₂ mixed gas may be about 5 weight % H₂ and about 95 weight % N₂. This method of preparing a phosphor may not only be applied to a GGAG:B³⁺-type phosphor containing Ce, but may also be applied variously to garnet-type phosphors activated by Ce.

The yellow phosphors based on embodiments of the present invention are excited by a blue light source to have a high luminescence efficiency. Also, the method of preparing yellow phosphors based on one embodiment of the present invention provide superior luminance and color purity and does not require a reducing atmosphere. A white light emitting device comprising the yellow phosphors based on embodiments of the present invention has a wide range for reproducing white colors so that a white light similar to a natural color may be obtained.

### EXAMPLES

Hereinafter, embodiment of the present invention will be described in more detail through specific examples. However, the spirit of the invention is not limited to these examples.

### Example 1

### Production of Gd₂Ga₂Al₃O₁₂:aCe³⁺,bB³⁺ Phosphor

Gd₂O₃, Ga₂O₃, Al₂O₃, Ce₂(CeO₄)₃, and B₂O₃ were mixed in a mole ratio of 3.0:2.0:3.0:0.09:b, respectively, where b has a value of 0.5, 1, 1.5, or 2, and the mixture together with a fluoride (AlF₃ in an about 20 mol % of GGAG) was thoroughly milled with acetone. The mixture was filtered, and then dried in an electric oven at about 80° C. After grinding in a mortar, the mixture was placed in a capped alumina crucible, to undergo curing at about 1550° C. for about 6 hours. The fired material was again ground in a mortar, after which it was washed with an about 5 weight % hydrochloric acid solution and dried again. Then, the cured matter was supplied while being mixed with acetone, and was ball-milled and separated through a sieve, and afterwards filtered and dried in an 80° C. electric oven. In a H₂/N₂ mixed gas (H₂: about 5 weight %, N₂: about 95 weight %) atmosphere, a second curing was performed to produce the GGAG:B³⁺-type phosphor Gd₃Ga₂Al₃O₁₂:0.09Ce³⁺,bB³⁺.

Referring to FIG. 3, the excitation spectrum shows a small peak at about 345 nm and a large peak at about 570 nm. Referring to FIG. 4, it is seen that the luminescence intensity is significantly affected by the number of moles of B³⁺. In the case of the Gd₃Ga₂Al₃O₁₂:Ce³⁺,B³⁺ phosphor, the luminescence intensity is the greatest when b=1.5.

### Example 2

### Production of Gd₃(Ga_{1-z}Al_{z})₂Al₃O₁₂:aCe³⁺,bB³⁺ Yellow Phosphor

Gd₂O₃, Ga₂O₃, Al₂O₃, Ce₂(CeO₄)₃, and B₂O₃ were mixed in a mole ratio of 3.0:2.0(1-y):(3+2.0y):3.0:0.09:1. Here, y is 0.1, 0.2, 0.3, or 0.4. The GGAG:B³⁺-type phosphor Gd₂(Ga_{1-y}Al_{y})₂Al₅O₁₂:0.09Ce³⁺,B³⁺ was synthesized by the same method as in Example 1.

Referring to FIG. 5, when the Ga³⁺ (4-coordination: about 0.47 Å, 6-coordination: about 0.62 Å) ion having a smaller ion radius is substituted in the place of the Al³⁺ (4-coordination: about 0.39 Å, 6-coordination: about 0.54 Å) ion, there is a movement towards long wavelengths, but there are no significant changes in the luminescence intensity.

### Example 3

### Production of (Gd₁₋ₐ)₃(Ga_{1-y}Si_{y})₂Al₃O_{12+y}:3aCe³⁺,bB³⁺ Phosphor

Gd₂O₃, Ga₂O₃, Si₂O₃, Al₂O₃, Ce₂(CeO₄)₃, and B₂O₃ were mixed in a mole ratio of 2.79:2.0(1-y):2.0y:3.0:0.21:1.5. Here, y is 0.1, 0.2, or 0.3. The GGAG:B³⁺-type phosphor Gd_{2.79}(Ga_{1-y}Si_{y})₂Al₃O_{12+y}:0.21Ce³⁺, 1.5B³⁺ was synthesized by the same method as in Example 1.

Referring to FIG. 6, it is seen that as Si is substituted for Ga, the luminescence intensity is greatly increased. This may be associated with the cation compensation vacancy defect generated when the Si having a +4 charge is substituted in the place of Ga having a +3 charge.

### Example 4

### Production of (Gd₁₋ₐ)₃(Ga_{1-y}Sc_{y})₂Al₃O₁₂:3aCe³⁺,bB³⁺ Phosphor

Gd₂O₃, Ga₂O₃, Sc₂O₃, Al₂O₃, Ce₂(CeO₄)₃, and B₂O₃ were mixed in a mole ratio of 2.79:2.0(1-y):2.0y:3.0:0.21:1.5. Here, y is 0.1, 0.2, or 0.3. The GGAG:B³⁺-type phosphor Gd_{2.79}(Ga_{1-y}Sc_{y})₂Al₃O₁₂:0.21Ce³⁺,1.5B³⁺ was produced by the same method as in Example 1.

Referring to FIG. 7, as Sc³⁺ having a coordination number only of 6 is substituted in the place of Ga³⁺ having coordination numbers of 4 and 6, the ratio of the intensity of about 570 nm with respect to that of about 520 nm is increased, so that the luminescence spectrum has an increased luminescenced intensity in the yellow ochre wavelengths.

### Example 5

### Production of (Gd₁₋ₐ)₃(Ga_{0.6}Al_{0.4})₂Al₃O₁₂:3aCe³⁺,B³⁺ Phosphor

Gd₂O₃, Ce₂(CeO₄)₃, Ga₂O₃, Al₂O₃, and B₂O₃ were mixed in a mole ratio of 3.0(1-a):3.0a:1.2:3.8:3.0:1. Here, 3a is 0.03, 0.05, 0.07, or 0.1. The GGAG:B³⁺-type phosphor (Gd₁₋ₐ)₃(Ga_{0.6}Al_{0.4})₂Al₃O₁₂:3aCe³⁺,B³⁺ was synthesized by the same method as in Example 1.

Referring to FIG. 7, when Ce³⁺ is substituted in the place of Gd³⁺, the maximum peak moves towards long wavelengths.

### Example 6

### Production of (Gd₁₋ₓ₋ₐTbₓ)₃(Ga_{0.6}Al_{0.4})₂Al₃O₁₂:3aCe³⁺,B³⁺ Phosphor

Gd₂O₃, Tb₂O₃, Ce₂(CeO₄)₃, Ga₂O₃, Al₂O₃, and B₂O₃ were mixed in a mole ratio of 3.0(0.93-x):3.0x:0.21:1.2:3.8:3.0:1.5. Here, x is 0, 0.1, 0.02, 0.03, or 0.04. The GGAG:B³⁺-type phosphor (Gd_{0.93-x}Tbₓ)₃(Ga_{0.6}Al_{0.4})₂Al₃O₁₂:0.21Ce³⁺,1.5B³⁺ was synthesized by the same method as in Example 1.

Referring to FIG. 8, it is seen that as the amount of Tb³⁺ substituted in the place of Gd³⁺ is increased, the phosphorescent intensity is decreased and then increased again.

### XRD Crystallinity Analysis Results

As described above, the XRD spectra are shown of a Gd₃Ga₂Al₃O₁₂;Ce³⁺ phosphor, in which B³⁺ ions have not been added, in FIG. 1 and of a Gd₃Ga₂Al₃O₁₂:Ce³⁺,B³⁺ phosphor, in which B³⁺ ions have been added, in FIG. 2. The XRD spectra of these phosphors were measured to examine changes in the crystal structure due to the addition of B³⁺ ions. This was performed using a CuKα ray and D/MAX-2200 Ultima/PC equipment. The peaks denoted by * on the XRD spectrum of FIG. 2 are peaks that have newly appeared or peaks that have large changes in the values of 1(f) with the addition of B³⁺ ions. The peaks occurring at about 26.7°, about 33.5°, and about 49.1° are newly appeared peaks, and while the intensity increased greatly for the peak occurring at about 60.4° with an increase in the content of B³⁺ ions, the intensity decreased greatly for the peak of about 68.70. These results show a significant effect of B³⁺ ions as a dopant on the crystal structure of GGAG, by which the phosphorescent intensity of GGAG is greatly affected.

### Manufacture of White Light Emitting Diode Using GGAG:B³⁺-Type Yellow Phosphor Based on One Embodiment of the Present Invention and Luminescence Spectrum Thereof

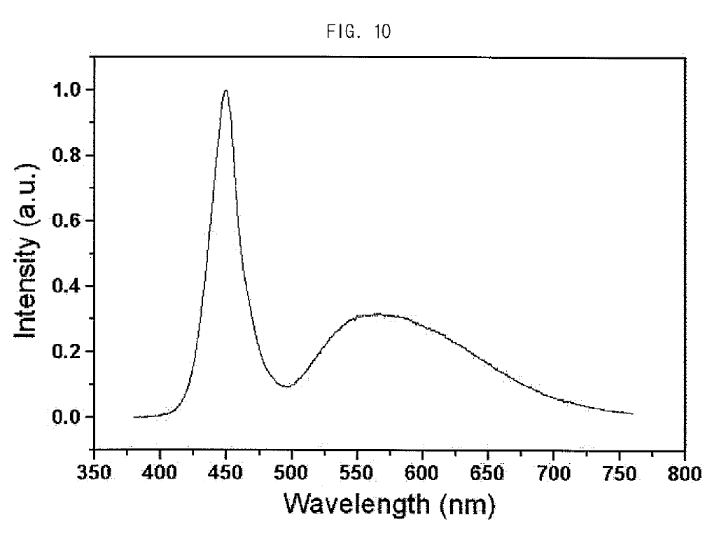

FIG. 10 is a luminescence spectrum of a white light emitting diode manufactured using a phosphor according to one embodiment of the present invention. Referring to FIG. 9, a white light emitting diode was manufactured using GGAG:B³⁺-type yellow phosphors produced in Examples 1 to 6.

On a sapphire substrate, a GaN nucleus formation layer about 25 nm, an n-GaN layer (metal: Ti/Al) about 1.2 μm, five layers of InGaN/GaN multi-quantum-well layers, an InGaN layer about 4 nm, a GaN layer about 7 nm, and a p-GaN layer (metal: Ni/Au) about 0.11 μm were sequentially formed to manufacture a blue light LED. Next, phosphors produced in Examples 1 to 6 mixed with epoxy were cast on a surface of the blue light LED to manufacture a white light emitting element. A typical luminescence spectrum of one of the fabricated LED devices is illustrated in FIG. 10. The white light emitting diode using yellow phosphors based on one embodiment of the present invention displays a main luminescence band in the range of about 550 to about 600 nm and a stable yellow region in the (0.32, 0.32) color coordinates, so that wavelengths may be converted on the blue light LED to provide a white light similar to a natural color.

Although certain embodiments of the present invention have been shown and described, it will be appreciated by those skilled in the art that changes may be made in these embodiments without departing from the principles and spirit of the invention, the scope of which is defined in the appended claims and their equivalents.

What is claimed is:

1. A yellow phosphor represented by Formula 1:
(Gd₁₋ₓTbₓ)₃(Ga_{1-y}Q_{y})₂Al₃O_{z}:aCe³⁺,bB³⁺ (1)
wherein Q is one or more elements selected from the group consisting of Si, Al, and Sc, wherein x is from about zero to about 0.1, wherein y is from about zero to about 0.5, wherein z is 12 when y is 0 or when Q is at least one of Al and Sc, wherein z is 12+y when Q is Si, wherein a is from about 0.03 to about 0.3, wherein b is from about 0.5 to about 4.

2. The yellow phosphor of claim 1, wherein a is from about 1 to about 10 mole % of (Gd, Tb), and wherein b is from about 0.5 to about 4 moles per 1 mole of (Gd₁₋ₓTbₓ)₃(Ga_{1-y}Q_{y})₂Al₃O_{z}.

3. The yellow phosphor of claim 1, wherein the yellow phosphor is produced by adding Ce in an amount from about 1 to about 10 mole % of a molar sum of Gd and Tb that are contained in Gd-containing compound(s) and Tb-containing compound(s).

4. The yellow phosphor of claim 1, wherein the yellow phosphor is produced by adding B in an amount from about 50 to about 400 mole % of (Gd₁₋ₓTbₓ)₃(Ga_{1-y}Q_{y})₂Al₃O_{z}.

5. The yellow phosphor of claim 1, wherein the phosphor has an excitation band ranging from about 420 to about 520 nm.

6. The yellow phosphor of claim 1, wherein the phosphor has a luminescence band ranging from about 475 to about 700 nm.

7. The yellow phosphor of claim 1, wherein Q is Si_{y1}Al_{y2}Sc_{y3}, wherein y is y1+y2+y3, wherein y1 is from about zero to about 0.5, wherein y2 is from about zero to about 0.5, and wherein y3 is from about zero to about 0.5.

8. The yellow phosphor of claim 1, wherein z is 12 when y1=y2=y3=0, wherein z is 12 when y1=0 and y2+y3≠0, and wherein z is 12+y when y1≠0.9.

9. A method of preparing the phosphor of claim 1, comprising:
mixing one or more compounds selected from the group consisting of Gd-containing compounds, Ga-containing compounds, Al-containing compounds, Ce-containing compounds, and B-containing compounds, and optionally at least one selected from the group consisting of Si-containing compounds, Tb-containing compounds and a Sc-containing compound; and
curing the compounds so as to produce the phosphor represented by Formula 1.

10. The method of claim 9, wherein one or more Ce-containing compounds are mixed in an amount from about 1 to about 10 mole % of a molar sum of Gd and Tb that are contained in one or more Gd-containing compounds and Tb-containing compounds.

11. The method of claim 9, wherein one or more B-containing compounds are mixed in an amount from about 50 to about 400 mole % of (Gd₁₋ₓTbₓ)₃(Ga_{1-y}Q_{y})₂Al₃O_{z}.

12. A white light emitting device comprising i) a yellow phosphor having a luminescence wavelength ranging from about 475 to about 700 nm and ii) a blue light emitting diode, wherein the yellow phosphor is represented by Formula 1:
(Gd₁₋ₓTbₓ)₃(Ga_{1-y}Q_{y})₂Al₃O_{z}:aCe³⁺,bB³⁺ (1)
wherein Q is one or more elements selected from the group consisting of Si, Al, and Sc, wherein x is from about zero to about 0.1, wherein y is from about zero to about 0.5, wherein z is 12 when y is 0 or when Q is at least one of Al and Sc, wherein z is 12+y when Q is Si, wherein a is from about 0.03 to about 0.3, and wherein b is from about 0.5 to about 4.

13. The white light emitting device of claim 12, wherein a is from about 1 to about 10 mole % of (Gd, Tb), and wherein b is from about 0.5 to about 4 moles per 1 mole of (Gd₁₋ₓTbₓ)₃(Ga_{1-y}Q_{y})₂Al₃O_{z}.

14. A yellow phosphor represented by Formula 2:
(Gd₁₋ₓTbₓ)₃(Ga_{1-y}Q_{y})₂Al₃O_{z}:aCe³⁺,bB³⁺ (1)
wherein Q is one or more elements selected from the group consisting of Si, Al, and Sc, wherein x is from about zero to about 0.1, wherein y is from about zero to about 0.5, wherein z is 12 when y is 0 or 12 when Q is at least one of Al and Sc, wherein z is 12+y when Q is Si, wherein a is from about 0.03 to about 0.3, and wherein b is from about 0.5 to about 4.

15. The yellow phosphor of claim 14, wherein a is from about 1 to about 10 mole % of (Gd, Tb), and wherein b is from about 0.5 to about 4 moles per 1 mole of (Gd₁₋ₓ₋ₐTbₓ)₃(Ga_{1-y}Q_{y})₂Al₃O_{z}.

16. The yellow phosphor of claim 14, wherein Q is Si_{y1}Al_{y2}Sc_{y3}, wherein y is y1+y2+y3, wherein y1 is from about zero to about 0.5, wherein y2 is from about zero to about 0.5, and wherein y3 is from about zero to about 0.5.

17. The yellow phosphor of claim 14, wherein z is 12 when y1=y2=y3=0, wherein z is 12 when y1=0 and y2+y3≠0, and wherein z is 12+y when y1≠0.

18. The yellow phosphor of claim 14, wherein the yellow phosphor has an excitation band ranging from about 420 to about 520 nm and a luminescence band ranging from about 475 to about 700 nm n.

19. A white light emitting device comprising i) a yellow phosphor having a luminescence wavelength ranging from about 475 to about 700 nm and ii) a blue light emitting diode, wherein the yellow phosphor is represented by Formula 2:
(Gd₁₋ₓ₋ₐTbₓ)₃(Ga_{1-y}Q_{y})₂Al₃O_{z}:3aCe³⁺,bB³⁺ (2)
wherein Q is one or more elements selected from the group consisting of Si, Al, and Sc, wherein x is from about zero to about 0.1, wherein y is from about zero to about 0.5, wherein z is 12 when y is 0 or 12 when Q is at least one of Al and Sc, wherein z is 12+y when Q is Si, wherein a is from about 0.03 to about 0.3, and wherein b is from about 0.5 to about 4.

20. The yellow phosphor of claim 19, wherein a is from about 1 to about 10 mole % of (Gd, Tb), and wherein b is from about 0.5 to about 4 moles per 1 mole of (Gd₁₋ₓ₋ₐTbₓ)₃(Ga_{1-y}Q_{y})₂Al₃O_{z}.
